(19) United States
(12) Patent Application Publication
(10) Pub. No.: US 2025/0372494 A1
(43) Pub. Date: Dec. 4, 2025

(54) COMPACT SEMICONDUCTOR PACKAGING USING A LEADLESS DISCRETE COMPONENT

(71) Applicant: SEMICONDUCTOR COMPONENTS INDUSTRIES, LLC, Scottsdale, AZ (US)

(72) Inventors: Jeonghyuk PARK, Incheon (KR); Gyuwan HAN, Incheon (KR); Keunhyuk LEE, Suzhou (CN)

(73) Assignee: SEMICONDUCTOR COMPONENTS INDUSTRIES, LLC, Scottsdale, AZ (US)

(21) Appl. No.: 18/731,625

(22) Filed: Jun. 3, 2024

(51) Int. Cl. H01L 23/498; H01L 21/48; H01L 23/00; H01L 23/15; H01L 23/31; H01L 25/18

(52) U.S. Cl. CPC H01L 23/49838; H01L 21/4853; H01L 23/15; H01L 23/3121; H01L 24/32; H01L 24/40; H01L 24/48; H01L 24/73; H01L 25/18; H01L 2224/32225; H01L 2224/40245; H01L 2224/48245; H01L 2224/73263; H01L 2224/73265; H01L 2924/1815

(57) ABSTRACT

An illustrative apparatus may include a substrate having a first portion and a second portion that is electrically isolated from the first portion. The apparatus may further include a leadless discrete component and a semiconductor die. The leadless discrete component may have a first surface and a second surface opposite the first surface, the first surface being physically coupled and electrically coupled to the first portion of the substrate, and the semiconductor die may be physically coupled and electrically coupled to the second portion of the substrate. The apparatus may further include a plurality of leads including a first lead electrically coupled to the first portion of the substrate, a second lead electrically coupled to the second portion of the substrate, and a third lead electrically coupled to the second surface of the leadless discrete component. Corresponding apparatuses and methods are also disclosed.

### TECHNICAL FIELD

This description relates to electronic device assemblies. More specifically, this description relates to semiconductor device packages.

### BACKGROUND

Packaging plays a critical role in ensuring the proper function, reliability, and case of use of electronic components. Proper packaging of electronic components may serve various roles. For example, one function of a package may be to protect a delicate silicon die inside the package from physical damage, contamination, electrostatic discharge (ESD), etc., since these threats could render the component inoperable if the die is not properly protected. Similarly, the package may also provide a barrier against moisture and exposure to other environmental elements that could lead to corrosion and malfunction of the component. Another role of the package may be to facilitate electrical connections between the internal circuitry of the component and external circuitry (e.g., of a circuit board to which the electronic component is coupled, etc.). For example, metal pins, leads, bumps, and other such features may allow for the electrical component to be soldered onto or otherwise connected to a printed circuit board. Heat dissipation may also be provided by packaging that is configured to facilitate heat transfer away from operational elements of the component (e.g., the die inside the package). Packaging may also include markings or labels that indicate important information about the component (e.g., a part number, manufacturer, electrical specifications, etc.) to facilitate proper identification, handling, and placement on the circuit board.

### SUMMARY

Various electronic components (e.g., integrated circuits, etc.) are packaged such that a molding material encloses internal electronics, while leads or other suitable electrical connections (e.g., pins, bumps, etc.) protrude from the molding material to facilitate the electronic component being connected to external circuitry. In some cases, the internal electronics of such a component may include only one or more dies, possibly disposed on a substrate or lead frame that is configured to facilitate electrical connections between different dies and/or between the die and the leads. In other cases, however, the package may also incorporate one or more discrete components such as small resistors, thermistors, capacitors, or the like. Common discrete component form factors may require significant space within the package (e.g., on a substrate, etc.) to properly connect leads of the discrete component to the die and/or to the leads of the larger package in a desirable way. Accordingly, as will be detailed below, apparatuses and devices described herein leverage leadless discrete components within the package to save space and provide other advantages described herein.

In one example implementation, an apparatus (e.g., an electronic device, a packaged semiconductor device, etc.) includes: 1) a substrate having a first portion and a second portion, the first portion being electrically isolated from the second portion; 2) a leadless discrete component having a first surface and a second surface opposite the first surface, the first surface being physically coupled and electrically coupled to the first portion of the substrate; 3) a semiconductor die physically coupled and electrically coupled to the second portion of the substrate; and 4) a plurality of leads including a first lead electrically coupled to the first portion of the substrate, a second lead electrically coupled to the second portion of the substrate, and a third lead electrically coupled to the second surface of the leadless discrete component.

In one general aspect of this example implementation, the third lead may be electrically coupled to the second surface of the leadless discrete component via a wire coupled using a wire bonding technique.

In another general aspect of this example implementation, the third lead may be electrically coupled to the second surface of the leadless discrete component via a clip.

In another general aspect of this example implementation, the first surface of the leadless discrete component may be physically coupled and electrically coupled to the first portion of the substrate via a solder material.

In another general aspect of this example implementation, the first surface of the leadless discrete component may be physically coupled and electrically coupled to the first portion of the substrate via a sintering material.

In another general aspect of this example implementation, the first surface of the leadless discrete component may be physically coupled and electrically coupled to the first portion of the substrate via a conductive adhesive material.

In another general aspect of this example implementation, the leadless discrete component may be a thermistor component configured for detecting a temperature within the apparatus during operation of the apparatus.

In another general aspect of this example implementation, the leadless discrete component may be one of: a resistor component configured to resist a current for a circuit of the apparatus during operation of the apparatus or a capacitor component configured to store an electrical charge for the circuit of the apparatus during the operation of the apparatus.

In another general aspect of this example implementation, the substrate may include a ceramic plate having a first side and a second side opposite the first side. The first side of the ceramic plate may be direct-bonded to a first metal layer that is patterned to include the first portion and the second portion. The second side of the ceramic plate may be direct-bonded to a second metal layer configured to facilitate heat transfer away from the apparatus.

In another general aspect of this example implementation, the apparatus may further include a molding compound that encapsulates the substrate, the leadless discrete component, and the semiconductor die. The molding compound may also partially encapsulate each of the first lead, the second lead, and the third lead of the plurality of leads.

In another general aspect of this example implementation, the apparatus may be an integrated circuit implementing a power module configured for use in an automotive application.

In another example implementation, an apparatus includes: 1) a substrate having a first portion and a second portion, the first portion being electrically isolated from the second portion; 2) a semiconductor die physically coupled to the second portion of the substrate; 3) a plurality of leads including a first lead electrically coupled to the first portion of the substrate, a second lead electrically coupled to the second portion of the substrate, and a third lead; and 4) a leadless discrete component having a first surface and a second surface opposite the first surface, the leadless discrete component being sandwiched between the substrate and the third lead, such that: (a) the first surface of the leadless discrete component is physically coupled and electrically coupled to the first portion of the substrate, and (b) the second surface of the leadless discrete component is physically coupled and electrically coupled to the third lead.

In a general aspect of this example implementation, the first surface of the leadless discrete component may be physically coupled and electrically coupled to the first portion of the substrate via a solder material. Additionally, the second surface of the leadless discrete component may be physically coupled and electrically coupled to the third lead via the solder material.

In another general aspect of this example implementation, the first surface of the leadless discrete component may be physically coupled and electrically coupled to the first portion of the substrate via a sintering material. Additionally, the second surface of the leadless discrete component may be physically coupled and electrically coupled to the third lead via the sintering material.

In another general aspect of this example implementation, the leadless discrete component may be a thermistor component configured for detecting a temperature within the apparatus during operation of the apparatus.

In another general aspect of this example implementation, the substrate may include a ceramic plate having a first side and a second side opposite the first side. The first side of the ceramic plate may be direct-bonded to a first metal layer that is patterned to include the first portion and the second portion. The second side of the ceramic plate may be direct-bonded to a second metal layer configured to facilitate heat transfer away from the apparatus.

In yet another example implementation, a method includes: 1) forming a substrate for use in a semiconductor package, the substrate including a first portion and a second portion, the first portion being electrically isolated from the second portion; 2) coupling a first surface of a leadless discrete component to the first portion of the substrate; 3) coupling a semiconductor die to the second portion of the substrate; 4) coupling a first conductive component to a first lead of a plurality of leads and to the first portion of the substrate; 5) coupling a second conductive component to a second lead of the plurality of leads and to the second portion of the substrate; and 6) coupling a third conductive component to a third lead of the plurality of leads and to a second surface of the leadless discrete component, the second surface being opposite the first surface.

In a general aspect of this example implementation, the first surface of the leadless discrete component may be coupled to the first portion of the substrate apart from the third lead. The third conductive component may be a wire that is coupled to the third lead and the second surface of the leadless discrete component using a wire bonding technique.

In another general aspect of this example implementation, the first surface of the leadless discrete component may be coupled to the first portion of the substrate apart from the third lead. The third conductive component may be a clip extending between the third lead and the second surface of the leadless discrete component.

In another general aspect of this example implementation, the leadless discrete component may be sandwiched between the first portion of the substrate and the third lead. The third conductive component may be one of a solder material, a sintering material, or a conductive adhesive material.

Each of the preceding example implementations and the various aspects described therewith will be understood to be illustrative of the types of implementations that are consistent with the following description. It will be understood that these examples are not intended to be limiting and that any of the aspects mentioned above or described herein may be used with any of the implementations in accordance with principles described herein. The details of these and other implementations are set forth in the accompanying drawings and the description below. Other features will also be apparent from the following description, drawings, and claims.

### BRIEF DESCRIPTION OF THE DRAWINGS

FIG. 1 shows an illustrative apparatus implementing compact semiconductor packaging using a leadless discrete component in accordance with principles described herein.

FIG. 2 contrasts illustrative aspects of conventional semiconductor packaging with compact semiconductor packaging using leadless discrete components in accordance with principles described herein.

FIG. 3A shows illustrative aspects of compact semiconductor packaging using a leadless discrete component and wire-based electrical couplings in accordance with principles described herein.

FIG. 3B shows, in a cross-sectional view, illustrative aspects of a solder-based implementation of the compact semiconductor packaging of FIG. 3A in accordance with principles described herein.

FIG. 3C shows, in a cross-sectional view, illustrative aspects of a sinter-based implementation of the compact semiconductor packaging of FIG. 3A in accordance with principles described herein.

FIG. 3D shows, in a cross-sectional view, illustrative aspects of an adhesive-based implementation of the compact semiconductor packaging of FIG. 3A in accordance with principles described herein.

FIG. 4A shows illustrative aspects of compact semiconductor packaging using a leadless discrete component and clip-based electrical couplings in accordance with principles described herein.

FIG. 4B shows, in a cross-sectional view, illustrative aspects of a solder-based implementation of the compact semiconductor packaging of FIG. 4A in accordance with principles described herein.

FIG. 4C shows, in a cross-sectional view, illustrative aspects of a sinter-based implementation of the compact semiconductor packaging of FIG. 4A in accordance with principles described herein.

FIG. 4D shows, in a cross-sectional view, illustrative aspects of an adhesive-based implementation of the compact semiconductor packaging of FIG. 4A in accordance with principles described herein.

FIG. 5A shows illustrative aspects of compact semiconductor packaging using a leadless discrete component sandwiched between a lead and the substrate in accordance with principles described herein.

FIG. 5B shows, in a cross-sectional view, illustrative aspects of a solder-based implementation of the compact semiconductor packaging of FIG. 5A in accordance with principles described herein.

FIG. 5C shows, in a cross-sectional view, illustrative aspects of a sinter-based implementation of the compact semiconductor packaging of FIG. 5A in accordance with principles described herein.

FIG. 5D shows, in a cross-sectional view, illustrative aspects of an adhesive-based implementation of the compact semiconductor packaging of FIG. 5A in accordance with principles described herein.

FIG. 6 shows illustrative aspects of an apparatus packaged using compact semiconductor packaging in accordance with principles described herein.

FIG. 7 shows an illustrative method for constructing an apparatus with compact semiconductor packaging using a leadless discrete component in accordance with principles described herein.

### DETAILED DESCRIPTION

Electronic components such as integrated circuits are packaged such that one or more semiconductor dies are encased in a molding material and are electrically connected to leads (or other suitable conductors such as pins, bumps, etc.) that extend out from the molding material to facilitate connecting the electronic component to other external circuitry. For instance, the electronic component may connect, by way of the leads, to a printed circuit board (PCB) to which other electronic components are also connected, or to other external circuitry circuit connected by other suitable mechanisms (besides via a PCB).

For certain electronic components packaged in this way, the encased electronics may only include one or more dies that are disposed on a lead frame or substrate. For example, a lead frame may provide a die pad on which a semiconductor die is placed and individual leads may be connected to the die by way of wire bonding or other suitable techniques. As another example, a substrate may be used that allows for a more complex pattern of connections to be made between multiple dies and/or between the die(s) and other components (e.g., discrete components such as small thermistors, resistors, capacitors, etc.) that are to be embedded with the die(s) within the package. The substrate may be implemented by a direct-bonded copper substrate or other such substrate in which layers of metal are direct-bonded to a non-conductive substrate such as a ceramic plate. The metal layer may be etched or otherwise processed to remove portions of the metal and thereby form planes and traces that may help implement the desired electrical couplings within the package.

If the package sizing (e.g., footprint, profile, etc.) for an integrated circuit component that includes at least one die and at least one discrete component in a unified package is not of particular importance for a given implementation, conventional surface mount technology (SMT) components (i.e., discrete components conforming to SMT package types such as 0201, 0402, 0603, etc.) may be used. For example, small traces and pads on a substrate within the package of the integrated circuit component may facilitate desired electrical connections between a die (or dies) in the package and one or more SMT components, as well as between these devices and leads emerging from the package.

A technical problem may arise, however, if it is desired that the package sizing for the integrated circuit component is small and typical SMT-based discrete components are used. Specifically, SMT components and other commonly-available discrete components with their own leads may make it difficult for a package to be made compact since these discrete components require a certain amount of space on the substrate for proper connections to be made. For example, suitably-sized pads for each lead of each discrete component may be required, as well as clearances between these pads (so that undesirable shorts between the leads do not occur), traces to form desired electrical paths for the discrete components, clearances between the traces, and so forth. Ultimately, even a single SMT component within an integrated circuit package may introduce a technical challenge if it is important for the package to be compact, since these components require significant space on the substrate to be properly attached and connected. In cases where a plurality of discrete components is desired within a single package, the technical problem would be exacerbated even further.

Accordingly, as detailed herein, apparatuses and devices may use leadless discrete components in certain ways within the package to save space and provide other advantages described herein. For apparatuses described herein, leadless discrete components may be used (e.g., in place of SMT components and/or other components that include leads that must be accommodated in the ways described above) for at least one, and possibly for each, discrete component that may be included in a design of a particular integrated circuit component. As one example, for an integrated circuit component such as a power module, one or more semiconductor dies could be disposed on a substrate (e.g., a direct-bonded copper substrate, etc.) within the package and a discrete thermistor component may be integrated with the die on the same substrate to be embedded within the same package. For example, the discrete thermistor component may be used to help monitor temperature within the package.

Rather than using an SMT-style thermistor component with leads that have to be accommodated with pads, traces, and suitable clearances, apparatuses according to principles described herein would rely on a leadless thermistor component that can be conveniently and flexibly disposed in a variety of locations on the substrate and can be electrically connected using various approaches detailed below. For example, rather than needing pads and traces to accommodate both leads of the thermistor, a leadless thermistor component may be disposed on a single pad and electrically connected using a wire-based or clip-based conductor that takes up none of the substrate area. In some implementations, the leadless thermistor component could even be disposed and connected directly under a lead (i.e., sandwiched between the lead and the substrate) such that the component does not even require its own pad, thereby saving even more space on the substrate.

The technical effect of replacing SMT components with leadless discrete components according to this technical solution is that design constraints, particular those related to substrate area, may be cased by the convenience and flexibility with which the discrete components may be placed in the design. More compact packages (e.g., in terms of both footprint and total area as well as in terms of profile and total volume of the package) may be made possible, which may in turn provide various technical and competitive advantages compared to packages that are less compact.

Various implementations will now be described in more detail with reference to the figures. It will be understood that the particular implementations described below are provided as non-limiting examples and may be applied in various situations. Additionally, it will be understood that other implementations not explicitly described herein may also fall within the scope of the claims set forth below. Compact semiconductor packaging using leadless discrete components in accordance with principles described herein may result in any or all of the technical benefits mentioned above, as well as various additional technical benefits that will be described and/or made apparent below.

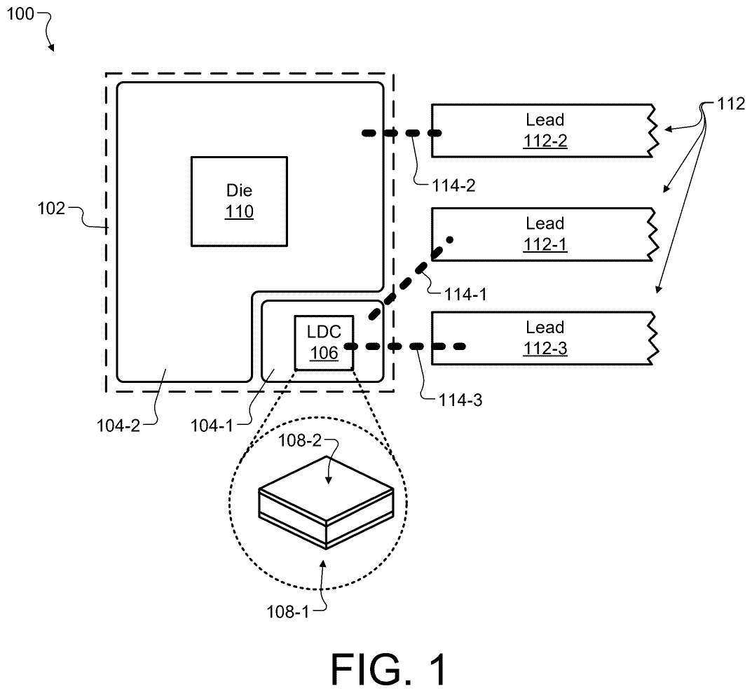

FIG. 1 shows an implementation 100 of illustrative packaging aspects for an apparatus that implements compact semiconductor packaging using a leadless discrete component in accordance with principles described herein. While implementation 100 does not depict all aspects that might be included in the apparatus (e.g., a completely packaged integrated circuit component), FIG. 1 illustrates certain principles for how such an apparatus may be constructed so as to be compact and enjoy other technical advantages described herein.

Implementation 100 represents a generalized implementation of an apparatus (e.g., an integrated circuit component packaged in accordance with principles described herein) from a top view, though it will be understood that various specific implementations of the apparatus in accordance with principles described and illustrated in relation to FIG. 1 may include various types of apparatuses used in various applications. As one particular example, the apparatus shown in implementation 100 could represent an integrated circuit implementing a power module configured for use in an automotive application. In other examples, the apparatus could represent other types of electronic components used for other types of applications. While various elements of implementation 100 are illustrated and described in relation to FIG. 1, additional details and other optional elements, which will be understood to apply to this implementation and/or to other implementations of the apparatus, will be illustrated and described in relation to other figures below.

As shown in FIG. 1, the apparatus of implementation 100 may include a substrate 102 having a first portion 104-1 and a second portion 104-2 that is electrically isolated from the first portion. Substrate 102 may represent a directed-bonded copper (DBC) substrate or other similar substrate that employs layers of a conductor (e.g., a metal such as copper, etc.) on an insulative tile (e.g., a ceramic plate, etc.) to facilitate electrical insulation between different the different portions 104-1 and 104-2, to distribute signals to various places (e.g., using signal traces, power or ground planes, etc.), to provide thermal management for the apparatus (e.g., due to high thermal conductivity of the conductor, which helps to dissipate heat), and so forth. As one example, substrate 102 may include a ceramic plate having a first side and a second side opposite the first side. The first side of the ceramic plate may be direct-bonded to a first metal layer (visible from the view of FIG. 1) that is patterned to include various different portions including portions 104-1 and 104-2. The second side of the ceramic plate (not shown in FIG. 1) may then be direct-bonded to a second metal layer that is configured to facilitate heat transfer away from the apparatus (e.g., acting as a heat sink to dissipate heat from heat-generating elements of the apparatus that will be described below). In other examples of substrate 102, both the first side and the second side may be patterned to include various portions (e.g., traces, planes, etc.) or both sides may include a solid plan of metal without any such electrically isolated portions. Moreover, it will be understood that both sides of the substrate may help dissipate heat.

A DBC-based implementations of substrate 102 (or another similar substrate such as described above) may offer various advantages for the packaging of apparatuses such as described herein. For example, this type of substrate 102 may be configured to handle relatively large currents and voltages due to efficient thermal management provided by the heat dissipation mentioned above. This may be useful for apparatuses such as power modules that generate and/or consume large amounts of power. For instance, apparatuses described herein could implement AC/DC converter modules configured to convert alternating current (AC) to direct current (DC) for computer power supplies or the like, DC/AC converter modules configured to convert DC to AC for regulating automotive electrical systems or the like, inverters for use in power systems or electric vehicles, motor drives used for appliances or electric vehicles, and various other examples as may serve a particular implementation. Other example advantages that DBC-based implementations of substrate 102 may offer include improved reliability (since the direct-bonding process between the ceramic and metal layers may create a strong and reliable connection), reduced size and weight (since DBC substrates are relatively thin and lightweight compared to other packaging materials), and so forth.

Despite the advantages of DBC and other similar substrates described above, it will be understood that substrate 102 may additionally or alternatively be implemented in other ways. For example, a leadframe constructed of copper or another suitable material may be formed with the pattern shown in FIG. 1 (e.g., with portions 104-1 and 104-2, etc.), and the direct-bonded layers of metal and ceramic described above may not be used.

Regardless of how substrate 102 is implemented, FIG. 1 shows that portion 104-1 may be electrically isolated from portion 104-2. For example, the shapes labeled as portions 104-1 and 104-2 may be understood to represent separate planes of direct-bonded metal on a ceramic tile (not explicitly shown) or to represent separate parts of a leadframe (which may be held together during the manufacturing process by tie bars or other such mechanisms that would later be removed and are not explicitly shown in FIG. 1). Additionally, while not shown in this example, it will be understood that additional portions of substrate 102 may also be included to implement pads for components, traces, and so forth.

As further shown in implementation 100, a leadless discrete component 106 (abbreviated as “LDC” due to space constraints in the figure) is shown in three-dimensional closeup (in the dotted circle expansion extending out of leadless discrete component 106) to have a first surface 108-1 and a second surface 108-2 opposite the first surface 108-1. First surface 108-1 will be understood to be both physically coupled and electrically coupled to first portion 104-1 of substrate 102, as shown. In other words, first surface 108-1 may represent the bottom of leadless discrete component 106 in this configuration, which may be soldered, sintered, attached by an adhesive, or otherwise physically and electrically coupled to portion 104-1. Meanwhile, second surface 108-2 may represent the top of the leadless discrete component 106 in this configuration, which is isolated from first surface 108-1 and from portion 104-1 but may be connected in other possible ways with other elements as will be detailed below.

Leadless discrete component 106 may be referred to by other names (e.g., a bondable component, etc.) and may be distinguished from discrete components packaged using surface mount technology (SMT) by the absence of leads on the component and the way that terminals of the component, implemented by conductive surfaces 108-1 and 108-2, may be electrically connected to other conductors. As will be made apparent with various examples described below, the leadless form factor of leadless discrete component 106 may allow for significant flexibility in how the component is physically and electrically coupled to other elements of the apparatus. For example, a top-side termination (e.g., constructed from a nickel-gold alloy or the like) may be well-suited for direct aluminum wire bonding or other suitable connection techniques. A bottom-side termination of leadless discrete component 106 may be well-suited for various mechanisms whereby the component is both physically and electrically coupled to a conductive surface below it (e.g., by way of soldering, silver sintering, conductive adhesion, etc.).

Leadless discrete component 106 may represent any type of discrete electronic component as may serve a particular implementation. In particular, it will be understood that leadless discrete component 106 may be any component selected to serve a particular purpose in the final function of the apparatus. As a first example, leadless discrete component 106 may be implemented as a thermistor component configured for detecting a temperature within the apparatus during operation of the apparatus. For instance, if the apparatus is a power module or other such integrated circuit, it may be useful to monitor the temperature of the module by using a thermistor that is embedded directly in the module near the die. As another example, leadless discrete component 106 may be implemented as one of a resistor component configured to resist a current for a circuit of the apparatus during operation of the apparatus or a capacitor component configured to store an electrical charge for the circuit of the apparatus during the operation of the apparatus. In either of these cases, the leadless discrete component may interoperate with other circuitry within the apparatus, such as by being connected with the die in a certain configuration to implement a particular circuit with desirable functionality. In still other examples, leadless discrete component 106 could be implemented as another type of discrete component such as an inductor, a diode, or the like.

Similar to the coupling between leadless discrete component 106 and portion 104-1 of substrate 102, a semiconductor die 110 (labeled “die 110”) is shown to be physically coupled and electrically coupled to portion 104-2 of substrate 102. Die 110 may represent any suitable semiconductor die as may serve a particular implementation. For instance, die 110 may implement a single transistor (e.g., a power transistor, etc.) or a circuit with a plurality of transistors. While only one die 110 is shown in the example of FIG. 1, it will be understood that certain apparatuses may be packaged with a plurality of dies in the same package. This is similar to the way that there could also be a plurality of discrete components (e.g., leadless discrete components, SMT components, a combination of both, etc.). In some cases, a single package of an integrated circuit component may include hybrid dies constructed from different semiconductor materials and/or using different fabrication processes or technologies. For example, hybrid dies may exhibit different properties, operate within different parameter ranges (e.g., a lower voltage die and a higher voltage die, etc.), and/or have other distinct traits that serve other purposes. In one example of a component with hybrid dies, a first die (e.g., die 110) could be fabricated on a silicon (Si) substrate, while a second die (not shown in FIG. 1) could be fabricated on a substrate of another suitable semiconductor material such as silicon carbide (SiC).

FIG. 1 also shows that implementation 100 may include a plurality of leads 112 (understood to each be shown only in part, as illustrated by the jagged cutoff representing the remainder of the leads that is not explicitly depicted). The plurality of leads 112 is shown to include a first lead 112-1 electrically coupled to portion 104-1 of substrate 102, a second lead 112-2 electrically coupled to portion 104-2 of substrate 102, and a third lead 112-3 electrically coupled to second surface 108-2 of leadless discrete component 106. To illustrate these electrical couplings, FIG. 1 shows dashed lines representing a conductive component 114-1 (coupled to lead 112-1 and to portion 104-1 of substrate 102), a conductive component 114-2 (coupled to lead 112-2 and to portion 104-2 of substrate 102), and a conductive component 114-3 (coupled to lead 112-3 and to surface 108-2 of leadless discrete component 106). While only three conductive components 114-1 through 114-3 are explicitly shown in this example, it will be understood that other conductive components between various elements of the apparatus could also be included in certain implementations. A few examples of such conductive components could include, without limitation, a conductive component coupled to die 110 and to another lead; a conductive component coupled to die 110 and to leadless discrete component 106; a conductive component coupled to either die 110 or leadless discrete component 106, and to one of the following: another semiconductor die (not depicted), another discrete component (not depicted), a particular portion of substrate 102 (e.g., one of portions 104-1 or 104-2 or another portion not depicted), another lead, or the like.

Conductive components 114-1 through 114-3 may each be implemented in any manner as may serve a particular implementation. For instance, in some examples, these conductive components could represent wires coupled to their respective elements by way of a wire bonding process or other suitable technique. In other examples, the conductive components could represent clips that electrically connect the elements shown. In still other examples, the conductive components could represent direct physical and electrical connections whereby the elements are physically attached to one another by way of a connection mechanism that provides the electrical connections (e.g., solder material, sintering material, conductive adhesive, etc.). In some cases, a combination of different types of conductive components may be employed within the same package or within the same implementation. For instance, certain connections could use wire bonding while other connections could utilize clips or direct connections. Each of these types of connections will be described and illustrated in more detail below with respect to specific implementations of the apparatus presented in the general implementation 100 of FIG. 1.

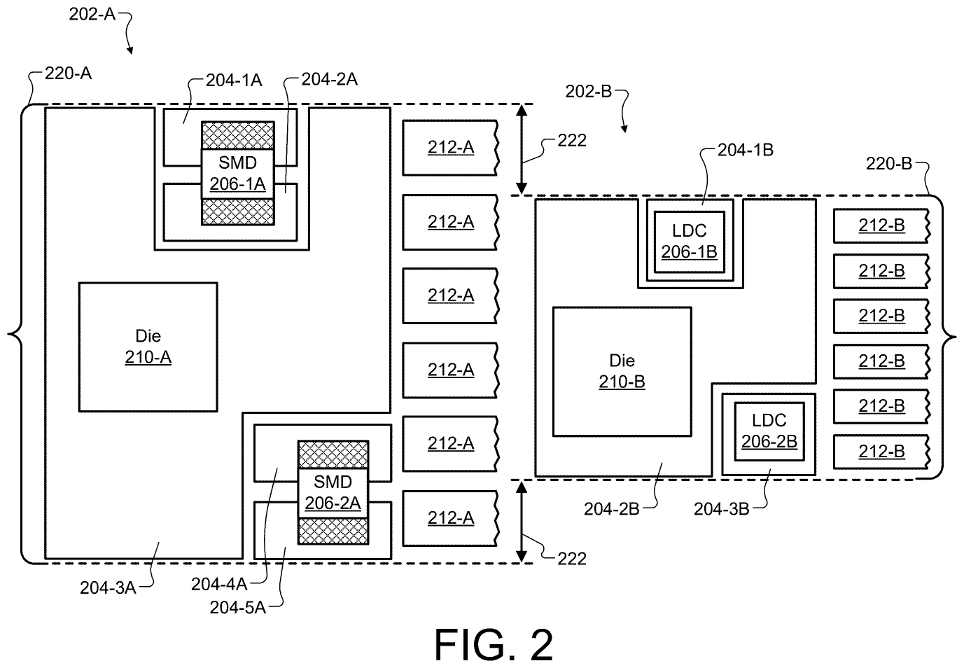

FIG. 2 contrasts illustrative aspects of conventional semiconductor packaging with compact semiconductor packaging using leadless discrete components in accordance with principles described herein. More particularly, as shown, various elements (each ending with ‘A’ designations) are shown on the left-hand side of FIG. 2 to illustrate aspects of conventional semiconductor packaging and to contrast these with like-numbered elements (each ending with ‘B’ designations) on the right-hand side of FIG. 2 to illustrate aspects of compact semiconductor packaging in accordance with principles described herein. Reference numbers in FIG. 2 that correspond to components described in relation to FIG. 1 are similar to the corresponding reference numbers in FIG. 1, though they begin with ‘2’ rather than ‘1’. For example, substrate 102 was described in FIG. 1, so FIG. 2 shows a corresponding substrate 202-A (for the conventional example) and a corresponding substrate 202-B (for the compact example). Similarly, since substrate 102 in implementation 100 was shown to include portions 104-1 and 104-2, substrate 202-A in FIG. 2 is shown to include various portions referred to as portions 204-A (including portions 204-1A, 204-2A, 204-3A, 204-4A, and 204-5A), while substrate 202-B in FIG. 2 is shown to include various portions referred to as portions 204-B (including portions 204-1B, 204-2B, and 204-3B).

While a single leadless discrete component 106 was illustrated and described in relation to FIG. 1, both example apparatuses in FIG. 2 are shown to include two discrete components to illustrate how the advantages of compact packaging described herein may increase the more discrete components are used.

Turning first to the conventional apparatus, FIG. 2 shows that, in place of leadless discrete component 106, the conventional apparatus in FIG. 2 includes a surface mount device 206-1A and a surface mount device 206-2A (both labeled “SMD” in the figure due to space constraints). As shown, and in contrast to leadless discrete component 106, each of the surface mount devices 206-1A and 206-2A is implemented by a discrete component with an SMT-style form factor. As such, these surface mount devices each include leads (the rectangles filled in with cross hatching) that are connected to individual portions of substrate 202-A that are carved out (with sufficient clearances, etc., to avoid circuit shorts) specifically for this purpose. More particularly, as shown, surface mount device 206-1A spans portions 204-1A and 204-2A of substrate 202-A while surface mount device 206-2A spans portions 204-4A and 204-5A of substrate 202-A. Moreover, just as die 110 was disposed on portion 104-2 of substrate 102, FIG. 2 shows a die 210-A disposed on portion 204-3A of substrate 202-A. While specific electrical connections are not shown in FIG. 2, a plurality of leads 212-A corresponding to leads 112 in FIG. 1 is also shown and will be understood to be configured to be electrically connected with various elements of the apparatus in accordance with principles that have been described.

FIG. 2 also shows various components of the compact apparatus to contrast the conventional apparatus. Specifically, in place of the leadless discrete component 106 described above (and instead of surface mount devices 206-1A and 206-2A), the compact apparatus in FIG. 2 is shown to include a leadless discrete component 206-1B and a leadless discrete component 206-2B (both abbreviated as “LDC” in the figure). These leadless discrete components have the same leadless form factor described above for leadless discrete component 106 and, as such, are shown to be disposed on respective portions 204-1B and 204-2B of corresponding substrate 202-B without the need for additional portions and clearances like those needed for the leads of surface mount devices 206-1A and 206-2A. A die 210-B is shown to be disposed on portion 204-2B of substrate 202-B and a plurality of leads 212-B (corresponding to leads 112 in FIG. 1 and leads 212-A in the conventional apparatus) is shown next to corresponding substrate 202-B. It will be understood that these leads may be electrically connected with various elements of the apparatus in accordance with principles that have been described.

Having introduced the various components of the two contrasting apparatuses in FIG. 2, attention will now be drawn to certain differences in the characteristics of the apparatuses to illustrate certain space saving advantages that leadless discrete components may help provide. Specifically, the conventional apparatus on the left is shown to have a width 220-A that is considerably larger than a width 220-B of the compact apparatus on the right. Dashed lines are drawn along both of these widths to show a compactization 222 representing a difference between widths 220-A and 220-B. As illustrated by compactization 222, the implementation of the apparatus employing the leadless discrete components may include all the same circuitry and functionality (with an identically sized die in the package) while supporting a smaller footprint for the apparatus. As has been mentioned, smaller substrates and overall package sizes may provide various advantages. Besides saving costs, these compact packages may also fit more easily and flexibly in more places (thereby facilitating design of circuits or devices that use the integrated circuit components implemented by these apparatuses). Smaller package sizes may also lead to improved cooling possibilities, reduced power, and other advantages.

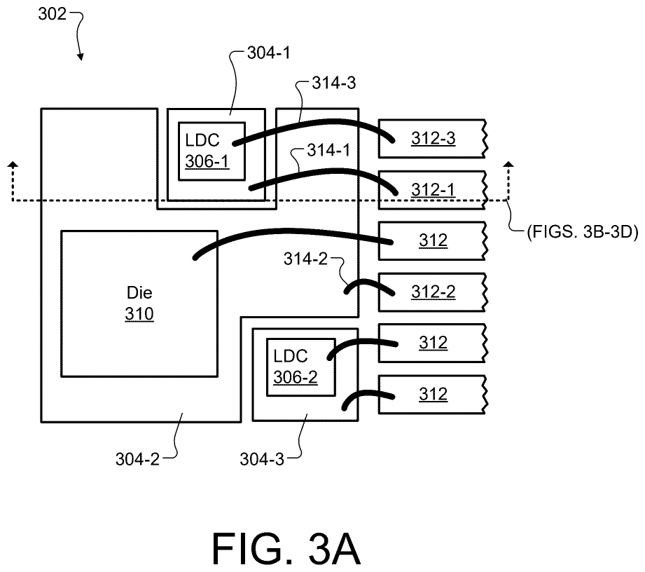

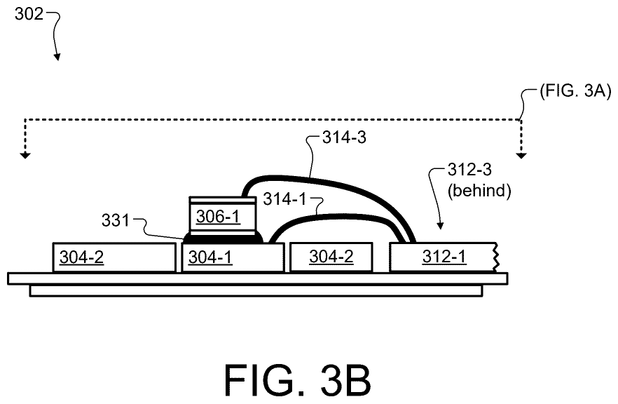

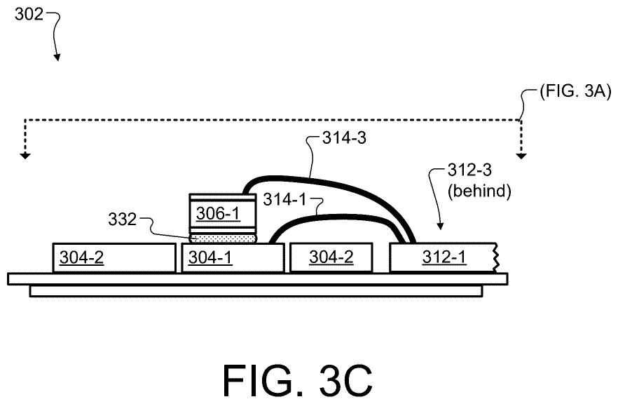

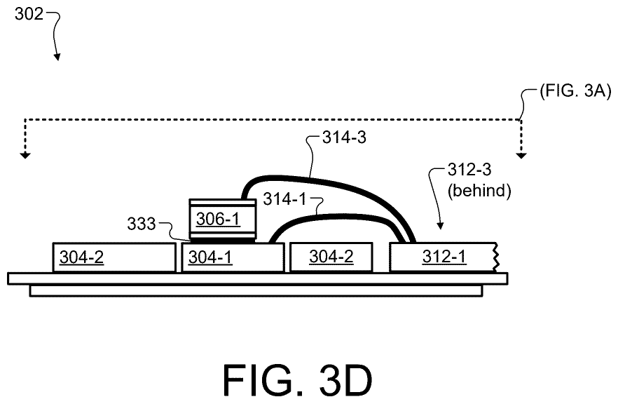

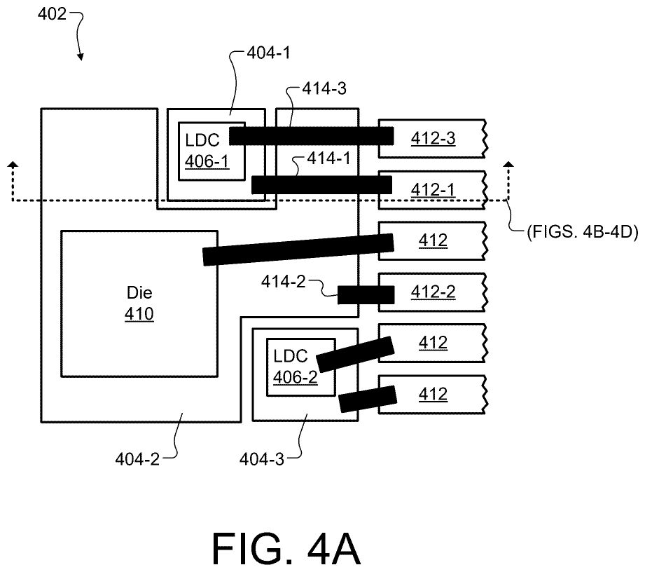

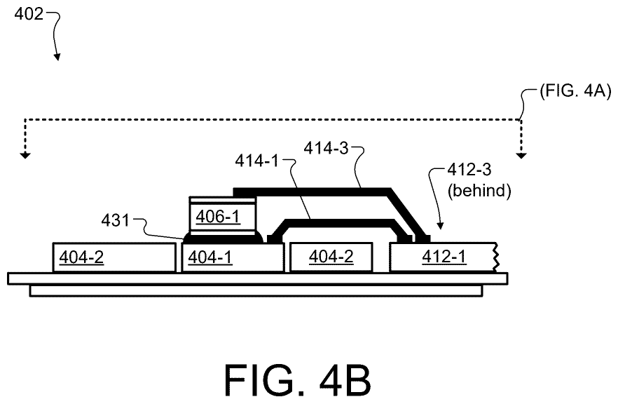

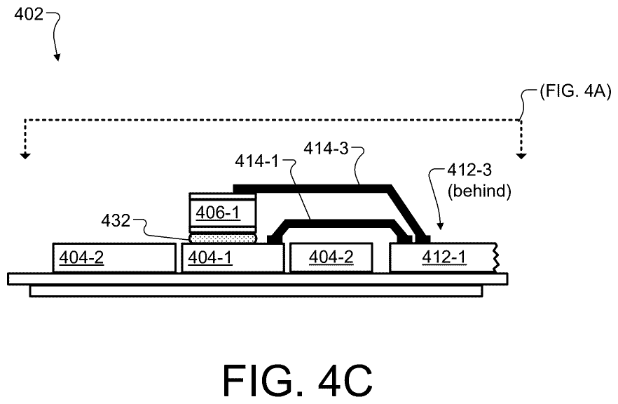

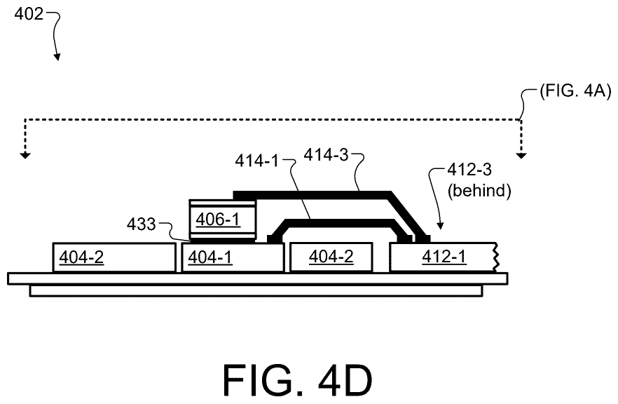

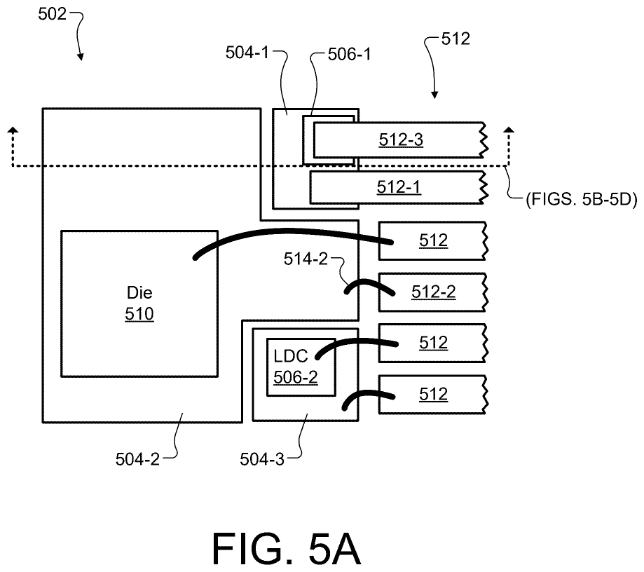

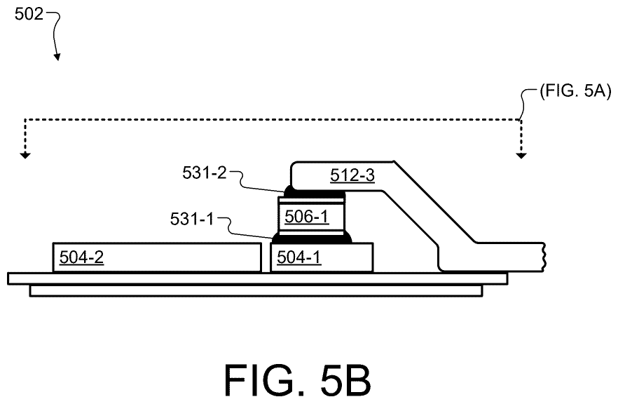

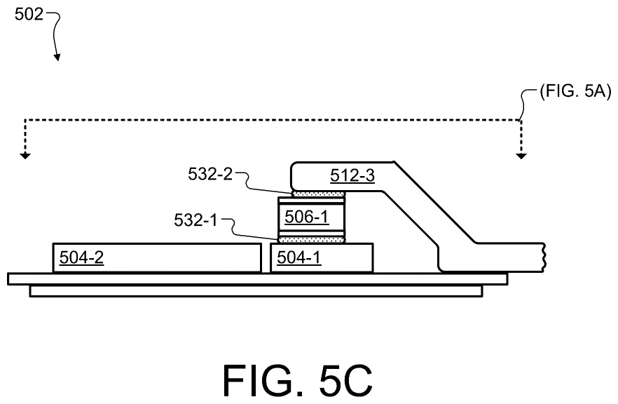

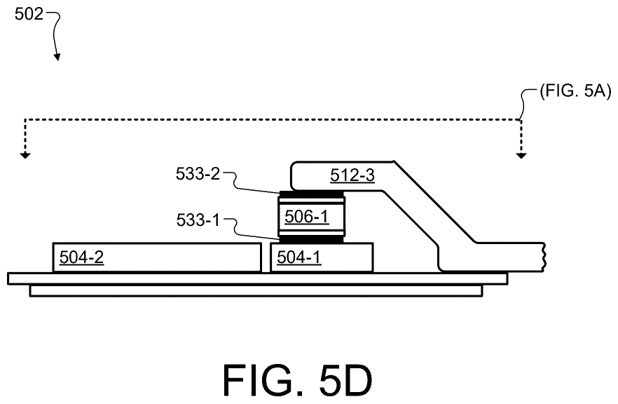

A variety of implementations of apparatuses in accordance with principles described herein will now be described in relation to FIGS. 3A-5D. Specifically, implementations in which a leadless discrete component is coupled via wire bonding will be illustrated and described in relation to FIGS. 3A-3D. Implementations in which a leadless discrete component is coupled via clips will be illustrated and described in relation to FIGS. 4A-4D. Implementations in which a leadless discrete component is coupled directly (e.g., by being disposed under a lead between the lead and the substrate) will be illustrated and described in relation to FIGS. 5A-5D. In each of these sets of examples, a first figure (i.e., FIGS. 3A, 4A, and 5A) shows an implementation of the apparatus similar to the compact apparatus shown in FIG. 2 and including corresponding numbering schemes (though the first digit is updated for each of these figures from the ‘2’ of FIGS. 2 to ‘3’, ‘4’, or ‘5’ to match the respective figure number). The other figures in each of these sets of examples show implementations from a cross-sectional side view and likewise use the same numbering schemes.

FIG. 3A shows illustrative aspects of compact semiconductor packaging using a leadless discrete component and wire-based electrical couplings in accordance with principles described herein. Specifically, as mentioned, similar elements as have already been described are shown to make up the apparatus of FIG. 3A, including a substrate 302 having a first portion 304-1, a second portion 304-2, and a third portion 304-3. Two leadless discrete components (both abbreviated as “LDC” in the figure) are disposed on this substrate, including a leadless discrete component 306-1 that is physically and electrically coupled to first portion 304-1 and a leadless discrete component 306-2 that is physically and electrically coupled to second portion 304-3. While not explicitly labeled in FIG. 3A, each of these leadless discrete components 306-1 and 306-2 will be understood to terminate in opposing surfaces corresponding to surfaces 108-1 and 108-2 described above. A die 310 is shown to be physically and electrically coupled to second portion 304-2 of substrate 302, and a plurality of leads 312 are shown to connect to various elements of the apparatus by way of conductive components that would be analogous to conductive components 114-1 through 114-3 in FIG. 1.

In the implementations of FIGS. 3A-3D, the conductive components are shown to be implemented by wires coupled to the various elements using a wire bonding technique. Various wires are not explicitly labeled in FIG. 3A, and it will be understood that the connections made by these wires are illustrative and could be different for other implementations. Three specific wires that are labeled, however, include a wire 314-1 that electrically couples a lead 312-1 and portion 304-1, a wire 314-2 that electrically couples a lead 312-2 and portion 304-2, and a wire 314-3 that electrically couples a lead 312-3 and a top surface of leadless discrete component 306-1. In this example, leadless discrete component 306-2 and die 310 are shown to be similarly connected by other (unlabeled) wires to other leads 312. A dotted line indicator labeled “FIGS. 3B-3D” is included within FIG. 3A to contextualize cross-sectional views that are depicted in each of FIGS. 3B-3D.

Accordingly, FIG. 3B shows, in a cross-sectional side view (similarly contextualized by a dotted line indicator labeled “FIG. 3A”), illustrative aspects of a solder-based implementation of the compact semiconductor packaging of FIG. 3A in accordance with principles described herein. Specifically, as shown from this side view, wire 314-1 couples portion 304-1 of substrate 302 to lead 312-1, while wire 314-3 couples the top surface of leadless discrete component 306-1 to lead 312-3 (labeled but not explicitly depicted from this view since it is behind lead 312-1). Each of these wires is shown to pass over portion 304-2 of substrate 302 so as to avoid electrically connecting leadless discrete component 306-1 to that portion (and thereby to the die). Rather, any desired connections to die 310 could be made by other conductive components (wires, etc.) as may serve a particular implementation (not shown).

In FIG. 3B, the first (bottom) surface of leadless discrete component 306-1 is shown to be physically coupled and electrically coupled to portion 304-1 of substrate 302 via a solder material 331. For example, in this implementation, leadless discrete component 306-1 may be soldered into place on portion 304-1 during the manufacturing process in any suitable manner. As a consequence of solder material 331, leadless discrete component 306-1 is not only physically coupled to portion 304-1 but also electrically coupled, such that current may flow between the first surface of the leadless discrete component, the solder, portion 304-1, wire 314-1, and lead 312-1. In other words, all of these elements will be understood to be on a same circuit node, just as the second (top) surface of leadless discrete component 306-1 is on a circuit node that includes wire 314-3 and lead 312-3.

FIG. 3C shows a similar cross-sectional view as FIG. 3B, except that, instead of a solder-based implementation, FIG. 3C shows a sinter-based implementation. Specifically, as shown, a sintering material 332 replaces solder material 331 to physically and electrically couple the first (bottom) surface of leadless discrete component 306-1 to portion 304-1 of substrate 302. For example, in this implementation, leadless discrete component 306-1 may be placed with the sintering material 332 (e.g., a fine or granular powder composed of conductive material such as silver, gold, copper, nickel alloy, etc.) between the bottom surface and portion 304-1 of substrate 302. Then, as part of the manufacturing process, a sintering operation (e.g., within a pressure chamber, etc.) may be performed to complete the sintering connection between the component and the substrate.

Similarly, FIG. 3D shows a similar cross-sectional view as FIGS. 3B and 3C, except that, instead of a solder-based implementation or a sinter-based implementation, FIG. 3D shows an adhesive-based implementation. Specifically, as shown, a conductive adhesive material 333 is used to physically and electrically couple the first (bottom) surface of leadless discrete component 306-1 to portion 304-1 of substrate 302. For example, in this implementation, leadless discrete component 306-1 may be placed with the conductive adhesive material 333 between the bottom surface and portion 304-1. In some examples, the conductive adhesive may cure or otherwise solidify as part of the manufacturing process. In any event, conductive adhesive material 333 may ultimately function to physically and electrically couple leadless discrete component 306-1 to first portion 304-1 in a similar manner as solder material 331 and/or sintering material 332.

In each of the cross-sectional side views of FIGS. 3B-3D, substrate 302 is shown to include not only the patterned top metal surface (including portions 304-1 and 304-2) but also two additional layers representing, for example, a ceramic (or other non-conductive) tile on which the patterned metal surface is disposed, and a bottom metal surface (e.g., direct bonded copper, etc.) that may function to dissipate heat and/or provide other advantages as described above. It will be understood that these layers may be implemented in different ways or could be omitted in certain examples as may serve a particular implementation.

FIG. 4A shows illustrative aspects of compact semiconductor packaging using a leadless discrete component and clip-based electrical couplings in accordance with principles described herein. Specifically, as mentioned, similar elements as have already been described are shown to make up the apparatus of FIG. 4A, including a substrate 402 having a first portion 404-1, a second portion 404-2, and a third portion 404-3. Two leadless discrete components (both abbreviated as “LDC” in the figure) are disposed on this substrate, including a leadless discrete component 406-1 that is physically and electrically coupled to first portion 404-1 and a leadless discrete component 406-2 that is physically and electrically coupled to second portion 404-3. While not explicitly labeled in FIG. 4A, each of these leadless discrete components 406-1 and 406-2 will be understood to terminate in opposing surfaces corresponding to surfaces 108-1 and 108-2 described above. A die 410 is shown to be physically and electrically coupled to second portion 404-2 of substrate 402, and a plurality of leads 412 are shown to connect to various elements of the apparatus by way of conductive components (analogous to conductive components 114-1 through 114-3 in FIG. 1).

In the implementations of FIGS. 4A-4D, the conductive components are shown to be implemented by clips coupled to the various elements. Various clips are not explicitly labeled in FIG. 4A, and it will be understood that the connections made by these clips are illustrative and could be different for other implementations. Three specific clips that are labeled, however, include a clip 414-1 that electrically couples a lead 412-1 and first portion 404-1, a clip 414-2 that electrically couples a lead 412-2 and portion 404-2, and a clip 414-3 that electrically couples a lead 412-3 and a top surface of leadless discrete component 406-1. In this example, leadless discrete component 406-2 and die 410 are shown to be similarly connected by other (unlabeled) clips to other leads 412. A dotted line indicator labeled “FIGS. 4B-4D” is included within FIG. 4A to contextualize cross-sectional views that are depicted in each of FIGS. 4B-4D.

Accordingly, FIG. 4B shows, in a cross-sectional side view (similarly contextualized by a dotted line indicator labeled “FIG. 4A”), illustrative aspects of a solder-based implementation of the compact semiconductor packaging of FIG. 4A in accordance with principles described herein. Specifically, as shown from this side view, clip 414-1 couples portion 404-1 of substrate 402 to lead 412-1, while clip 414-3 couples the top surface of leadless discrete component 406-1 to lead 412-3 (labeled but not explicitly depicted from this view since it is behind lead 412-1). Each of these clips is shown to pass over portion 404-2 of substrate 402 so as to avoid electrically connecting leadless discrete component 406-1 to that portion (and thereby to the die). Rather, any desired connections to die 410 could be made by other conductive components (clips, wires, etc.) as may serve a particular implementation (not shown).

In FIG. 4B, the first (bottom) surface of leadless discrete component 406-1 is shown to be physically coupled and electrically coupled to portion 404-1 of substrate 402 via a solder material 431. For example, in this implementation, leadless discrete component 406-1 may be soldered into place on portion 404-1 during the manufacturing process in any suitable manner. As a consequence of solder material 431, leadless discrete component 406-1 is not only physically coupled to portion 404-1 but also electrically coupled, such that current may flow between the first surface of the leadless discrete component, the solder, portion 404-1, clip 414-1, and lead 412-1. In other words, all of these elements will be understood to be on a same circuit node, just as the second (top) surface of leadless discrete component 406-1 is on a circuit node that includes clip 414-3 and lead 412-3.

FIG. 4C shows a similar cross-sectional view as FIG. 4B, except that, instead of a solder-based implementation, FIG. 4C shows a sinter-based implementation. Specifically, as shown, a sintering material 432 replaces solder material 431 to physically and electrically couple the first (bottom) surface of leadless discrete component 406-1 to portion 404-1 of substrate 402. For example, in this implementation, leadless discrete component 406-1 may be placed with the sintering material 432 (e.g., silver sinter, etc.) between the bottom surface and portion 404-1 of substrate 402. Then, as part of the manufacturing process, a sintering operation (e.g., within a pressure chamber, etc.) may be performed to complete the sintering connection between the component and the substrate.

Similarly, FIG. 4D shows a similar cross-sectional view as FIGS. 4B and 4C, except that, instead of a solder-based implementation or a sinter-based implementation, FIG. 4D shows an adhesive-based implementation. Specifically, as shown, a conductive adhesive material 433 is used to physically and electrically couple the first (bottom) surface of leadless discrete component 406-1 to portion 404-1 of substrate 402. For example, in this implementation, leadless discrete component 406-1 may be placed with the conductive adhesive material 433 between the bottom surface and portion 404-1. In some examples, the conductive adhesive may cure or otherwise solidify as part of the manufacturing process. In any event, conductive adhesive material 433 may ultimately function to physically and electrically couple leadless discrete component 406-1 to first portion 404-1 in a similar manner as solder material 431 and/or sintering material 432.

As described above in relation to FIGS. 3A-3D, each of the cross-sectional side views of FIGS. 4B-4D show that substrate 402 may include not only the patterned top metal surface (including portions 404-1 and 404-2) but also two additional layers representing, for example, a ceramic (or other non-conductive) tile on which the patterned metal surface is disposed, and a bottom metal surface (e.g., direct bonded copper, etc.) that may function to dissipate heat and/or provide other advantages as described above. It will be understood that these layers may be implemented in different ways or could be omitted in certain examples as may serve a particular implementation.

FIG. 5A shows illustrative aspects of compact semiconductor packaging using a leadless discrete component sandwiched between a lead and the substrate in accordance with principles described herein. Specifically, as mentioned, similar elements as have already been described are shown to make up the apparatus of FIG. 5A, including a substrate 502 having a first portion 504-1, a second portion 504-2, and a third portion 504-3 that are all electrically isolated from one another. Two leadless discrete components (both abbreviated as “LDC” in the figure) are disposed on this substrate, including a leadless discrete component 506-1 that is physically and electrically coupled to first portion 504-1 and a leadless discrete component 506-2 that is physically and electrically coupled to second portion 504-3. While not explicitly labeled in FIG. 5A, each of these leadless discrete components 506-1 and 506-2 will be understood to terminate in opposing surfaces corresponding to surfaces 108-1 and 108-2 described above. A die 510 is shown to be physically and electrically coupled to second portion 504-2 of substrate 502, and a plurality of leads 512 are shown to connect to various elements of the apparatus by way of conductive components (analogous to conductive components 114-1 through 114-3 in FIG. 1).

In the implementations of FIGS. 5A-5D, several conductive components are shown to be implemented by wires coupled to various elements. For example, a wire 514-2 (corresponding to wire 314-2 of FIGS. 3A-3D and to clip 414-2 of FIGS. 4A-4D) is shown to electrically couple a lead 512-2 to portion 504-2 of substrate 502. Other wires not explicitly labeled in FIG. 5A will be understood to make illustrative connections that could be different for other implementations. In contrast to FIGS. 3A and 4A, however, the couplings between leads 512-1 and 512-3 are not made by wires, clips, or other such conductive components, but, rather, are made directly by virtue of the physical proximity of the leads to the elements they connect to. More particularly, as shown, leadless discrete component 506-1 may be sandwiched between substrate 502 and a lead 512-3 such that: 1) a first (bottom) surface of leadless discrete component 506-1 is physically coupled and electrically coupled to portion 504-1 of substrate 502, and 2) a second (top) surface of leadless discrete component 506-1 is physically coupled and electrically coupled to a third lead 512-3. Similarly, as further shown, portion 504-1 of substrate 502 may be directly connected (e.g., by way of soldering material, sintering material, etc.) to a first lead 512-1.

While leads 512-1 and 512-3 are shown to make direct connections (e.g., by way of soldering or sintering material or the like, rather than via a wire or clip or other such conductive component) to elements of the apparatus of FIG. 5A, other leads 512 (including lead 512-2, as mentioned above) are shown to still be connected by other means (wires in this example). As such, FIG. 5A illustrates that a combination of coupling techniques (e.g., wires, clips, direct connections, etc.) may be used in a single apparatus implementation. For example, in this case, leadless discrete component 506-1 is shown to be connected by being sandwiched between lead 512-3 and portion 504-1 of substrate 502, while leadless discrete component 506-2 is shown to be connected to portion 504-3 of substrate 502 using wires similarly as described above in relation to FIGS. 3A-3D. Similar to other examples above, a dotted line indicator labeled “FIGS. 5B-5D” is included within FIG. 5A to contextualize cross-sectional views that are depicted in each of FIGS. 5B-5D.

Accordingly, FIG. 5B shows, in a cross-sectional side view (similarly contextualized by a dotted line indicator labeled “FIG. 5A”), illustrative aspects of a solder-based implementation of the compact semiconductor packaging of FIG. 5A in accordance with principles described herein. Specifically, as shown from this side view, leadless discrete component 506-1 is sandwiched between portion 504-1 of substrate 502 and lead 512-3 and is physically and electrically coupled to these elements by solder material 531-1 (coupling portion 504-1 to the bottom surface of leadless discrete component 506-1) and solder material 531-2 (coupling the top surface of leadless discrete component 506-1 to lead 512-3). For example, in this implementation, leadless discrete component 506-1 may be soldered into place on portion 504-1 during the manufacturing process in any suitable manner. Lead 512-3 may then be soldered on the top surface of the component at a later point in the process. Alternatively, these operations could be reversed and leadless discrete component 506-1 could be first coupled to lead 512-3 and later coupled to portion 504-1 of substrate 502.

FIG. 5C shows a similar cross-sectional view as FIG. 5B, except that, instead of a solder-based implementation, FIG. 5C shows a sinter-based implementation. Specifically, as shown, a sintering material 532-1 replaces solder material 531-1 to physically and electrically couple the first (bottom) surface of leadless discrete component 506-1 to portion 504-1 of substrate 502, while a sintering material 532-2 replaces solder material 531-2 to physically and electrically couple the second (top) surface of leadless discrete component 506-1 to lead 512-3. For example, in this implementation, leadless discrete component 506-1 may be placed in between the substrate and the lead with the sintering material 532-1 and 532-2 (e.g., silver sinter, etc.) and, as part of the manufacturing process, a sintering operation (e.g., within a pressure chamber, etc.) may be performed to complete the sintering connection between the component, the substrate, and the lead.

Similarly, FIG. 5D shows a similar cross-sectional view as FIGS. 5B and 5C, except that, instead of a solder-based implementation or a sinter-based implementation, FIG. 5D shows an adhesive-based implementation. Specifically, as shown, a conductive adhesive material 533-1 is used to physically and electrically couple the first (bottom) surface of leadless discrete component 506-1 to portion 504-1 of substrate 502, while a conductive adhesive material 533-2 is used to physically and electrically couple the second (top) surface of leadless discrete component 506-1 to lead 512-3. For example, in this implementation, leadless discrete component 506-1 may be positioned with the conductive adhesive material 533-1 and 533-2 as shown during the manufacturing process. In some examples, the conductive adhesive may also cure or otherwise solidify as part of the manufacturing process. In any event, conductive adhesive material 533-1 and 533-2 may ultimately function to physically and electrically couple leadless discrete component 506-1 in a similar manner as solder material 531-1 and 531-2 and/or sintering material 532-1 and 532-2.

While each of FIGS. 5B-5D showed the same type of material (e.g., solder material, sintering material, or conductive adhesive material) being used for both couplings of leadless discrete component 506-1 as it is sandwiched between substrate 502 and lead 512-3, it will be understood that the material coupling the top surface and the bottom surface may be different in certain implementations. For example, a conductive adhesive could be used on the bottom and solder used on the top, or sintering material could be used on the bottom and solder used on the top, or any other suitable combination as may serve a particular implementation.

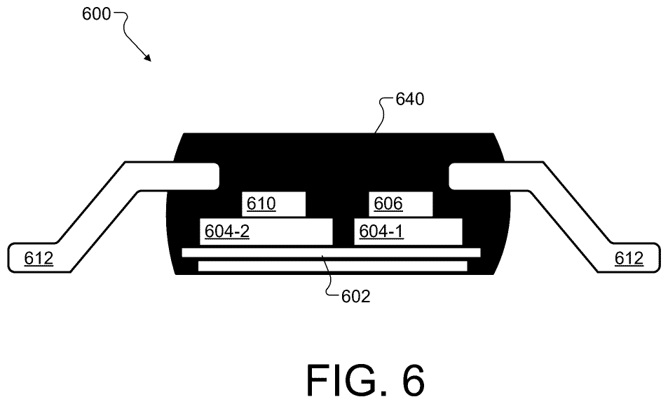

FIG. 6 shows illustrative aspects of an apparatus 600 packaged using compact semiconductor packaging in accordance with principles described herein. More particularly, while other examples have shown various elements that are being packaged together while the packaged apparatus itself is in an unfinished state, FIG. 6 shows a cross-sectional view of apparatus 600 to represent an apparatus that is finished (though not necessarily to scale and omitting various details, such as the particular conductive components used to connect elements of the apparatus within the package). As shown, the reference numbers used for apparatus 600 follow a similar pattern as other apparatuses described above. For instance, a substrate 602 (e.g., a DBC substrate or the like) is shown to include a portion 604-1 on which a leadless discrete component 606 is disposed and a portion 604-2 on which a semiconductor die 610 is disposed. Various leads 612 are also shown to be extending outwards from the package to facilitate connections to other circuitry. Moreover, apparatus 600 is shown to include a molding compound 640 that: 1) encapsulates substrate 602 (including its various portions 604-1 and 604-2), leadless discrete component 606, and semiconductor die 610; and 2) partially encapsulates each of the plurality of leads 612, while allowing part of the leads to emerge from the molding compound to facilitate other connections to be made with external circuitry.

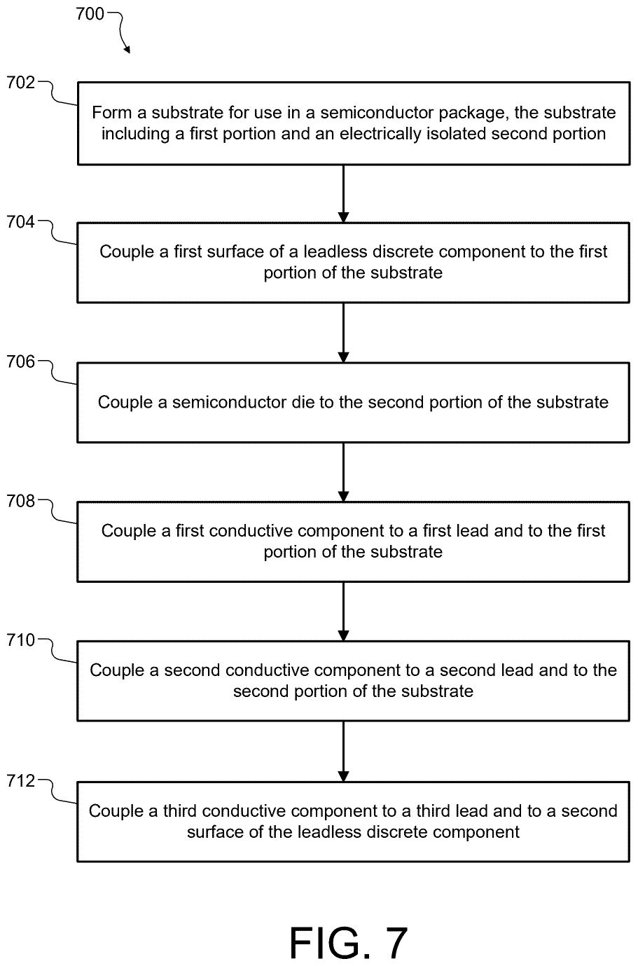

FIG. 7 shows an illustrative method 700 for constructing an apparatus with compact semiconductor packaging using a leadless discrete component in accordance with principles described herein. For example, an apparatus such as apparatus 600 or any of the other example apparatus implementations described above may be assembled or constructed based on the steps of FIG. 7. While FIG. 7 shows illustrative operations 702-712 according to one implementation, other implementations of method 700 may omit, add to, reorder, and/or modify any of the operations 702-712 shown in FIG. 7. In some examples, multiple operations shown in FIG. 7 or described in relation to FIG. 7 may be performed concurrently (e.g., in parallel) with one another, rather than being performed sequentially as illustrated and/or described. Each of operations 702-712 will now be described in more detail.

At operation 702, a substrate may be formed for use in a semiconductor package. For example, any suitable techniques for substrate preparation may be performed to create a substrate such as any of the substrates described herein. In the example of a direct bonded copper substrate, for example, operation 702 may involve preparing the ceramic substrate, preparing a copper foil (e.g., with a particular thickness to meet the application's requirements), direct bonding the copper foil to the ceramic substrate (e.g., using a high-temperature brazing process or the like), etching the desired pattern into the copper on one side of the substrate to generate a first portion and a second portion that are electrically isolated from one another, and other suitable tasks such as may be appropriate for a particular application (e.g., drilling vias, applying a solder mask, performing surface finishing, etc.).

At operation 704, a first surface of a leadless discrete component may be coupled to the first portion of the substrate. For example, the leadless discrete component may be implemented by any of the leadless discrete components described herein, such as a resistor, thermistor, capacitor, or other discrete component having a leadless package (e.g., with terminals implemented as first (bottom) and second (top) surfaces). The coupling of the first surface of the leadless discrete component at operation 704 may involve any suitable material and/or technique as may serve a particular implementation. For instance, the leadless discrete component may be coupled to the first portion using a soldering operation, a sintering operation, an operation relying on a conductive adhesive, or another suitable operation.

At operation 706, a semiconductor die is coupled to the second portion of the substrate. For example, similar to the coupling of the leadless discrete component described above in relation to operation 704, the coupling of the semiconductor die to the second portion of the substrate may involve any suitable material and/or technique as may serve a particular implementation. For instance, the semiconductor die may be coupled to the first portion using a solder material, sintering material, adhesive material, or the like.

At operation 708, a first conductive component may be coupled to a first lead of a plurality of leads and to the first portion of the substrate. For example, the first conductive component may be a wire that is coupled by a wire bonding technique, a clip that is coupled by a clip bonding technique, or the like. As another example, a direct coupling may be performed whereby the first lead is itself coupled to the first portion of the substrate using a soldering operation, sintering operation, or the like. In this case, the first conductive component would be the solder material, sintering material, or conductive adhesive material that provides the direct coupling.

At operation 710, a second conductive component may be coupled to a second lead of the plurality of leads and to the second portion of the substrate. This second conductive component may be the same or different from the first conductive component described above in relation to operation 708. For example, here again, the second conductive component may be implemented by a wire, a clip, or an amount of solder material, sintering material, conductive adhesive material, or another suitable conductor configured to electrically couple the second lead to the second portion of the substrate.

At operation 712, a third conductive component may be coupled to a third lead of the plurality of leads and to a second surface of the leadless discrete component. For example, the second surface may be opposite the first surface, such that the first surface can be considered a bottom surface while the second surface can be considered a top surface for one particular orientation of the leadless discrete component. As with the first and second conductive components above, the third conductive component may be any of the conductive components described herein and may be the same or different from the first and second conductive components described above.

Various ways that each of operations 702-712 may be performed have been described. To be more specific, a few possible implementations are now described that correspond with particular implementations illustrated and described above. As a first possible implementation, the first surface of the leadless discrete component may be coupled to the first portion of the substrate at operation 704 apart from the third lead. The third conductive component coupled at operation 712 may then be a wire that is coupled to the third lead and the second surface of the leadless discrete component using a wire bonding technique. This type of implementation is illustrated specifically in FIGS. 3A-3D.

As another possible implementation, the first surface of the leadless discrete component could again be coupled to the first portion of the substrate at operation 704 apart from the third lead. The third conductive component coupled at operation 712 may then be a clip extending between the third lead and the second surface of the leadless discrete component. This type of implementation is illustrated specifically in FIGS. 4A-4D.

As yet another possible implementation, the leadless discrete component may be sandwiched between the first portion of the substrate and the third lead. As such, and as mentioned above, the third conductive component in this type of implementation could be one of a solder material, a sintering material, or a conductive adhesive material. This type of implementation is illustrated specifically in FIGS. 5A-5D.

A number of embodiments have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

The various apparatus and techniques described herein may be implemented using various semiconductor processing and/or packaging techniques. Some embodiments may be implemented using various types of semiconductor processing technologies associated with semiconductor substrates including, but not limited to, for example, Silicon (Si), Gallium Arsenide (GaAs), Silicon Carbide (SiC), and/or so forth.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

It will be understood that, although the terms first, second, etc. may be used herein to describe various elements, these elements should not be limited by these terms. These terms are only used to distinguish one element from another. A first element could be termed a second element, and, similarly, a second element could be termed a first element, without departing from the scope of the implementations of the disclosure. As used herein, the term and/or includes any and all combinations of one or more of the associated listed items.

While certain features of the described implementations have been illustrated as described herein, many modifications, substitutions, changes, and equivalents may occur to those skilled in the art. It is therefore to be understood that the appended claims are intended to cover such modifications and changes as fall within the scope of the implementations. It will be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components, and/or features of the different implementations described. As such, the scope of the present disclosure is not limited to the particular combinations hereafter claimed, but instead extends to encompass any combination of features or example implementations described herein irrespective of whether or not that particular combination has been specifically enumerated in the accompanying claims at this time.

What is claimed is:

1. An apparatus comprising:
a substrate having a first portion and a second portion, the first portion being electrically isolated from the second portion;
a leadless discrete component having a first surface and a second surface opposite the first surface, the first surface being physically coupled and electrically coupled to the first portion of the substrate;
a semiconductor die physically coupled and electrically coupled to the second portion of the substrate; and
a plurality of leads including a first lead electrically coupled to the first portion of the substrate, a second lead electrically coupled to the second portion of the substrate, and a third lead electrically coupled to the second surface of the leadless discrete component.

2. The apparatus of claim 1, wherein the third lead is electrically coupled to the second surface of the leadless discrete component via a wire coupled using a wire bonding technique.

3. The apparatus of claim 1, wherein the third lead is electrically coupled to the second surface of the leadless discrete component via a clip.

4. The apparatus of claim 1, wherein the first surface of the leadless discrete component is physically coupled and electrically coupled to the first portion of the substrate via a solder material.

5. The apparatus of claim 1, wherein the first surface of the leadless discrete component is physically coupled and electrically coupled to the first portion of the substrate via a sintering material.

6. The apparatus of claim 1, wherein the first surface of the leadless discrete component is physically coupled and electrically coupled to the first portion of the substrate via a conductive adhesive material.

7. The apparatus of claim 1, wherein the leadless discrete component is a thermistor component configured for detecting a temperature within the apparatus during operation of the apparatus.

8. The apparatus of claim 1, wherein the leadless discrete component is one of:
a resistor component configured to resist a current for a circuit of the apparatus during operation of the apparatus; or
a capacitor component configured to store an electrical charge for the circuit of the apparatus during the operation of the apparatus.

9. The apparatus of claim 1, wherein:
the substrate includes a ceramic plate having a first side and a second side opposite the first side;
the first side of the ceramic plate is direct-bonded to a first metal layer that is patterned to include the first portion and the second portion; and
the second side of the ceramic plate is direct-bonded to a second metal layer configured to facilitate heat transfer away from the apparatus.

10. The apparatus of claim 1, further comprising a molding compound that:
encapsulates the substrate, the leadless discrete component, and the semiconductor die; and
partially encapsulates each of the first lead, the second lead, and the third lead of the plurality of leads.

11. The apparatus of claim 1, wherein the apparatus is an integrated circuit implementing a power module configured for use in an automotive application.

12. An apparatus comprising:
a substrate having a first portion and a second portion, the first portion being electrically isolated from the second portion;
a semiconductor die physically coupled to the second portion of the substrate;
a plurality of leads including a first lead electrically coupled to the first portion of the substrate, a second lead electrically coupled to the second portion of the substrate, and a third lead; and
a leadless discrete component having a first surface and a second surface opposite the first surface, the leadless discrete component being sandwiched between the substrate and the third lead, such that:
the first surface of the leadless discrete component is physically coupled and electrically coupled to the first portion of the substrate, and
the second surface of the leadless discrete component is physically coupled and electrically coupled to the third lead.

13. The apparatus of claim 12, wherein:
the first surface of the leadless discrete component is physically coupled and electrically coupled to the first portion of the substrate via a solder material; and
the second surface of the leadless discrete component is physically coupled and electrically coupled to the third lead via the solder material.

14. The apparatus of claim 12, wherein:
the first surface of the leadless discrete component is physically coupled and electrically coupled to the first portion of the substrate via a sintering material; and
the second surface of the leadless discrete component is physically coupled and electrically coupled to the third lead via the sintering material.

15. The apparatus of claim 12, wherein the leadless discrete component is a thermistor component configured for detecting a temperature within the apparatus during operation of the apparatus.

16. The apparatus of claim 12, wherein:
the substrate includes a ceramic plate having a first side and a second side opposite the first side;
the first side of the ceramic plate is direct-bonded to a first metal layer that is patterned to include the first portion and the second portion; and
the second side of the ceramic plate is direct-bonded to a second metal layer configured to facilitate heat transfer away from the apparatus.

17. A method comprising:
forming a substrate for use in a semiconductor package, the substrate including a first portion and a second portion, the first portion being electrically isolated from the second portion;
coupling a first surface of a leadless discrete component to the first portion of the substrate;
coupling a semiconductor die to the second portion of the substrate;
coupling a first conductive component to a first lead of a plurality of leads and to the first portion of the substrate;
coupling a second conductive component to a second lead of the plurality of leads and to the second portion of the substrate; and
coupling a third conductive component to a third lead of the plurality of leads and to a second surface of the leadless discrete component, the second surface being opposite the first surface.

18. The method of claim 17, wherein:
the first surface of the leadless discrete component is coupled to the first portion of the substrate apart from the third lead; and
the third conductive component is a wire that is coupled to the third lead and the second surface of the leadless discrete component using a wire bonding technique.

19. The method of claim 17, wherein:
the first surface of the leadless discrete component is coupled to the first portion of the substrate apart from the third lead; and
the third conductive component is a clip extending between the third lead and the second surface of the leadless discrete component.

20. The method of claim 17, wherein:
the leadless discrete component is sandwiched between the first portion of the substrate and the third lead; and
the third conductive component is one of a solder material, a sintering material, or a conductive adhesive material.
